(19) United States
(12) Patent Application Publication
(10) Pub. No.: US 2025/0038095 A1
(43) Pub. Date: Jan. 30, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventors: Junho LEE, Suwon-si (KR); Insik HAN, Suwon-si (KR); Shlege LEE, Suwon-si (KR)

(21) Appl. No.: 18/739,548

(22) Filed: Jun. 11, 2024

(30) Foreign Application Priority Data
Jul. 27, 2023 (KR) 10-2023-0098285

(51) Int. Cl. H01L 23/498; H01L 21/768; H01L 23/00; H01L 25/065

(52) U.S. Cl. CPC H01L 23/49838; H01L 21/76882; H01L 23/49816; H01L 24/05; H01L 24/13; H01L 25/0655; H01L 2224/05005; H01L 2224/05025; H01L 2224/13026; H01L 2224/131; H01L 2924/0665; H01L 2924/1205; H01L 2924/1431; H01L 2924/15311; H01L 2924/182

(57) ABSTRACT

A semiconductor package includes: a package substrate having a first surface and a second surface, wherein the package substrate includes a plurality of first substrate pads and a plurality of second substrate pads that are electrically connected to each other; a semiconductor device mounted on the package substrate and electrically connected to the plurality of first substrate pads; conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and a semiconductor element mounted on the package substrate, wherein the semiconductor element has metal oxide barriers that are provided on the conductive members and a side surface of the semiconductor element.

### CROSS-REFERENCE TO RELATED APPLICATION

This application claims priority under 35 U.S.C. § 119 to Korean Patent Application No. 10-2023-0098285, filed on Jul. 27, 2023 in the Korean Intellectual Property Office (KIPO), the disclosure of which is incorporated by reference herein in its entirety.

### TECHNICAL FIELD

Example embodiments of the present inventive concept relate to a semiconductor package and a method of manufacturing the semiconductor package. More particularly, example embodiments of the present inventive concept relate to a semiconductor package including a semiconductor element and a method of manufacturing the same.

### DISCUSSION OF THE RELATED ART

During a process of mounting semiconductor elements such as capacitors on a package substrate, spacing distances between the semiconductor elements and the package substrate may exist. When the spacing distances are not sufficient, voids may occur in a molding member (e.g., an Epoxy Molding Compound) that covers the semiconductor elements that are disposed on the package substrate. If the spacing distances are not sufficient, foreign substances may remain in gaps that are between the semiconductor elements and the package substrate during a following cleaning process, and a short failure may occur due to the foreign substances.

### SUMMARY

According to example embodiments of the present inventive concept, a semiconductor package includes: a package substrate having a first surface and a second surface opposite to each other, wherein the package substrate includes a plurality of first substrate pads and a plurality of second substrate pads that are exposed from the first surface and are electrically connected to each other; a semiconductor device mounted on the first surface of the package substrate and electrically connected to the plurality of first substrate pads; conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and a semiconductor element mounted on the package substrate via the conductive bumps and spaced apart from the semiconductor device, wherein the semiconductor element has metal oxide barriers that are provided on the conductive members and are provided on a side surface of the semiconductor element.

According to example embodiments of the present inventive concept, a semiconductor package includes: a package substrate having a first surface and a second surface opposite to each other, wherein the package substrate includes a plurality of first substrate pads and a plurality of second substrate pads that are exposed from the first surface and are electrically connected to each other; conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and a semiconductor element mounted on the package substrate via the conductive bumps, wherein the semiconductor element has metal oxide barriers that are provided on the conductive members and that cover at least a portion of a side surface of the semiconductor element.

According to example embodiments of the present inventive concept, a semiconductor package includes: a package substrate having a first surface and a second surface opposite to each other, wherein the package substrate includes a plurality of first substrate pads and a plurality of second substrate pads that are exposed from the first surface and are electrically connected to each other; a semiconductor device mounted on the first surface of the package substrate and electrically connected to the plurality of first substrate pads; conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and a semiconductor element mounted on the package substrate via the conductive bumps to be electrically connected to the plurality of second substrate pads, wherein the semiconductor element has metal oxide barriers provided on the conductive members and provided on a side surface of the semiconductor element, wherein the semiconductor element includes a multi-layer ceramic capacitor (MLCC).

### BRIEF DESCRIPTION OF THE DRAWINGS

The above and other features of the present inventive concept will become more apparent by describing in detail example embodiments thereof, with reference to the accompanying drawings, in which:

FIG. 1 is a plan view illustrating a semiconductor package in accordance with example embodiments of the present inventive concept.

FIG. 2 is a cross-sectional view taken along the line A-A′ in FIG. 1.

FIG. 3 is an enlarged cross-sectional view illustrating portion ‘B’ in FIG. 2.

FIGS. 4, 5, 6, 7, 8, 9 and 10 are views illustrating a method of manufacturing a semiconductor package in accordance with example embodiments of the present inventive concept.

### DETAILED DESCRIPTION OF EMBODIMENTS

Hereinafter, example embodiments of the present inventive concept will be explained in detail with reference to the accompanying drawings.

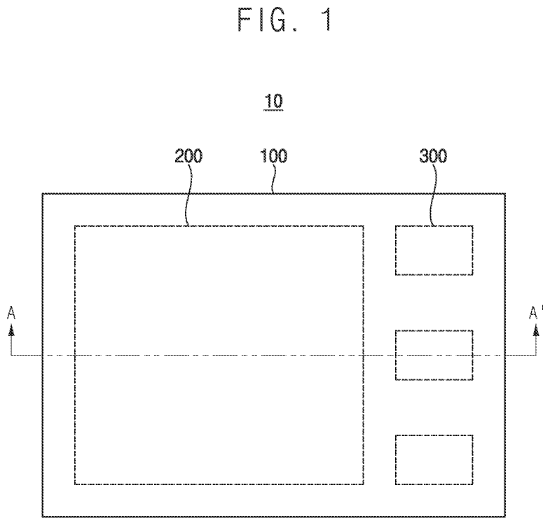

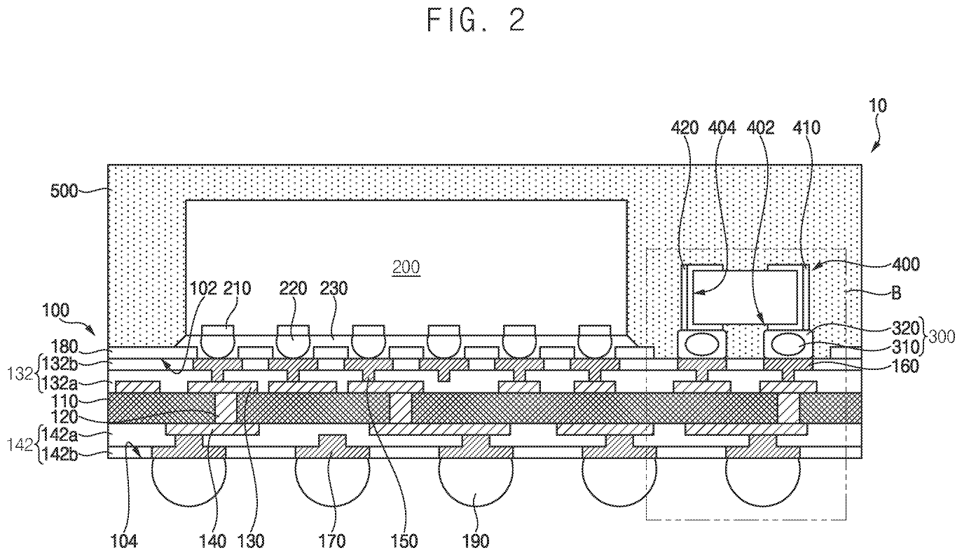

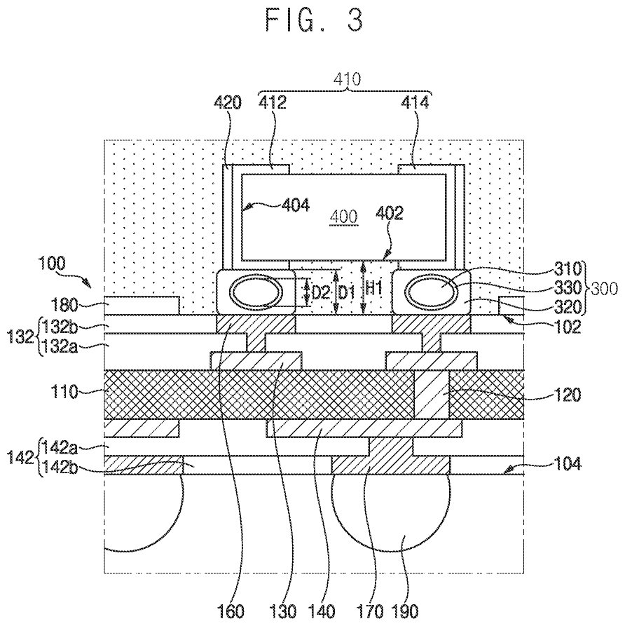

FIG. 1 is a plan view illustrating a semiconductor package in accordance with example embodiments of the present inventive concept. FIG. 2 is a cross-sectional view taken along the line A-A′ in FIG. 1. FIG. 3 is an enlarged cross-sectional view illustrating portion ‘B’ in FIG. 2.

Referring to FIGS. 1 to 3, a semiconductor package 10 may include a package substrate 100, at least one semiconductor device 200, which is disposed on the package substrate 100, and at least one semiconductor element 400, which is disposed on the package substrate 100 and spaced apart from the at least one semiconductor device 200, and a plurality of conductive bumps 300, which are disposed between the at least one semiconductor element 400 and the package substrate 100 to support the at least one semiconductor element 400. The semiconductor package 10 may further include a sealing member 500.

In example embodiments of the present inventive concept, the semiconductor device 200 and the semiconductor element 400 may be connected to each other through wirings in the package substrate 100. The semiconductor device 200 may include chip bumps 220 that are provided respectively on chip pads 210 on a lower surface thereof. The semiconductor element 400 may be mounted on the package substrate 100 via the plurality of conductive bumps 300. The semiconductor device 200 and the semiconductor element 400 may be mounted on the package substrate 100, and may be electrically connected to each other via the chip bumps 220 and the conductive bumps 300.

In example embodiments of the present inventive concept, the package substrate 100 may be a substrate having a first surface 102 and a second surface 104 opposite to each other. For example, the package substrate 100 may include a printed circuit board (PCB), a flexible substrate, a tape substrate, etc. The printed circuit board may be a multilayer circuit board having vias and various circuits therein.

The package substrate 100 may include a core layer 110, a plurality of conductive through vias 120, upper conductive patterns 130, an upper insulating layer 132, lower conductive patterns 140, a lower insulating layer 142, a plurality of first to third substrate pads 150, 160 and 170, and an uppermost insulating layer 180. The package substrate 100 may further include a plurality of external connection bumps 190.

The core layer 110 may include a non-conductive material layer. The core layer 110 may include a reinforcing polymer or the like. The conductive through via 120 may penetrate the core layer 110 and may electrically connect the upper conductive pattern 130 and the lower conductive pattern 140 to each other.

The first and second substrate pads 150 and 160 may be provided in the first surface 102 of the package substrate 100 and may be electrically connected to the upper conductive patterns 130. The upper conductive patterns 130 may extend inside the package substrate 100. The upper conductive patterns 130 may be provided in the upper insulating layer 132. The upper conductive patterns 130 may extend on an upper surface of the core layer 110. For example, at least portions of the upper conductive patterns 130 may be used as landing pads for the first and second substrate pads 150 and 160.

The third substrate pads 170 may be disposed in the second surface 104 of the package substrate 100 and may be electrically connected to the lower conductive patterns 140. The lower conductive patterns 140 may extend within the package substrate 100. The lower conductive patterns 140 may be provided in the lower insulating layer 142. The lower conductive patterns 140 may extend on a lower surface of the core layer 110 opposite to the upper surface. For example, at least portions of the lower conductive patterns 140 may be used as landing pads for the third substrate pads 170.

The upper conductive patterns 130 and the lower conductive patterns 140 may include a power wire or a ground wire as a power net for supplying power to electronic components that are mounted on the package substrate 100. The first to third substrate pads 150, 160 and 170 may include a power pad or a ground pad connected to the power wire or ground wire. Additionally, the first to third substrate pads 150, 160 and 170 may further include a plurality of substrate signal wirings and substrate signal pads for transmitting data signals to the electronic components.

For example, the upper and lower conductive patterns 130 and 140, and the first to third substrate pads 150, 160, and 170 may each include, for example, aluminum (Al), copper (Cu), tin (Sn), and nickel (Ni), gold (Au), platinum (Pt), or an alloy thereof. The upper and lower conductive patterns 130 and 140, and the first to third substrate pads 150, 160, and 170 may be formed by a plating process, an electroless plating process, a vapor deposition process, etc.

The upper insulating layer 132 may be provided in the first surface 102 of the package substrate 100. The upper insulating layer 132 may cover the upper conductive patterns 130 and may expose the first and second substrate pads 150 and 160 from the first surface 102 of the package substrate 100. The upper insulating layer 132 may cover the first surface 102 of the package substrate 100 except upper surfaces of the first and second substrate pads 150 and 160.

The uppermost insulating layer 180 may be provided on the first surface 102 of the package substrate 100. The uppermost insulating layer 180 may be provided on the upper insulating layer 132. The uppermost insulating layer 180 may cover at least portions of the first and second substrate pads 150 and 160. However, the present inventive concept is not limited thereto. For example, the uppermost insulating layer 180 might not cover the first and second substrate pads 150 and 160.

The uppermost insulating layer 180 may have an opening area for mounting the semiconductor element 400 on the first surface 102 of the package substrate 100. The uppermost insulating layer 180 may expose the second substrate pads 160 through the opening area.

The uppermost insulating layer 180 may be formed of an insulating material and may protect the package substrate 100 from the outside. The uppermost insulating layer 180 may be formed of an oxide layer or a nitride layer, or may be formed of a double layer of an oxide layer and a nitride layer. The uppermost insulating layer 180 may be formed of an oxide layer, for example, a silicon oxide layer (SiO₂) using a high-density plasma chemical vapor deposition (HDP-CVD) process.

The lower insulating layer 142 may be provided on the second surface 104 of the package substrate 100 to cover the lower conductive patterns 140 and expose the third substrate pads 170. The lower insulating layer 142 may cover the second surface 104 of the package substrate 100 except lower surfaces of the third substrate pads 170. For example, the upper and lower insulating layers 132 and 142 may include a polymer, a dielectric film, a silicon oxide layer, a silicon nitride layer, or a silicon oxynitride layer. The upper and lower insulating layers 132 and 142 may be formed by a vapor deposition process, a spin coating process, etc.

The third substrate pads 170 may be provided in the second surface 104 of the package substrate 100, and the external connection bumps 190 may be provided, respectively, on the third substrate pads 170 for electrical connection with an external device. The external connection bumps 190 may be exposed by the lower insulating layer 142. For example, the external connection bump 190 may be a solder ball. The semiconductor package 10 may be mounted on a module substrate via the solder balls to form a semiconductor module.

Although only some substrate pads and the wirings are illustrated in the drawings, it may be understood that the number and arrangement of the substrate pad and the wirings are an example, and the present inventive concept is not limited thereto. Since the wirings as well as the substrate pads are well known in the art to which the present inventive concept pertains, illustration and description concerning the above elements will be omitted.

In example embodiments of the present inventive concept, the semiconductor device 200 may be disposed on the first surface 102 of the package substrate 100. The semiconductor device 200 may be mounted on the package substrate 100 using a flip chip bonding method. The semiconductor device 200 may be electrically connected to the first substrate pads 150. The chip pads 210 of the semiconductor device 200 may be electrically connected to the first substrate pads 150 of the package substrate 100 through the chip bumps 220 that serve as conductive connection members. For example, the chip bumps 220 may include micro bumps (uBumps).

In addition, the semiconductor device 200 may be mounted on the package substrate 100 by using a wire bonding method. The chip pads 210 of the semiconductor device 200 may be electrically connected to the first substrate pads 150 of the package substrate 100 through bonding wires that serve as conductive connection members.

A first adhesive 230 may be underfilled between the semiconductor device 200 and the package substrate 100. The first adhesive 230 may reinforce a gap between the semiconductor device 200 and the package substrate 100.

In example embodiments of the present inventive concept, each of the conductive bumps 300 may include a bump body 310 and a conductive member 320 at least surrounding the bump body 310. The conductive bumps 300 may be disposed on the first surface 102 of the package substrate 100. The conductive bumps 300 may be respectively disposed on the second substrate pads 160 within the opening area. For example, the conductive bumps 300 may include a Cu Core Solder Ball (CCSB).

The conductive bumps 300 may support the semiconductor element 400 and may be disposed on a lower surface 402 of the semiconductor element 400. The conductive bumps 300 may support vertical stress that is applied to an upper surface that is opposite to the lower surface 402 of the semiconductor element 400. Each of the conductive members 320 may have a cavity to accommodate the bump body 310. The conductive members 320 may at least partially surround the bump bodies 310 and accommodate the bump bodies 310 in the cavities respectively. The conductive members 320 may be supported by the bump bodies 310 respectively.

In a reflow process for mounting the semiconductor element 400 on the package substrate 100, the conductive members 320 may be bonded to the second substrate pads 160. The bump bodies 310 may have a first melting point. The conductive members 320 may have a second melting point that is lower than the first melting point. Since the first melting point of the bump bodies 310 is higher than the second melting point of the conductive members 320, the conductive members 320 may be melted and the bump bodies 310 might not be melted during the reflow process. Since the bump bodies 310 do not melt when the conductive members 320 are melted, the bump bodies 310 may secure sufficient spaces between the semiconductor element 400 and the package substrate 100.

The bump bodies 310 may include a first metal material. For example, the first metal material may be nickel (Ni), bismuth (Bi), indium (In), aluminum (Al), copper (Cu), lead (Pb), gold (Au), silver (Ag), and/or a polymer, etc.

The conductive members 320 may include a second metal material different from the first metal material. For example, the second metal material may include a solder material.

The conductive bumps 300 may have a first diameter D1. The bump bodies 310 may have a second diameter D2. During the reflow process, the bump bodies 310 may maintain the second diameter D2. For example, the first diameter D1 of each of the conductive bumps 300 may be within a range of about 40 μm to about 60 μm. The second diameter D2 of each of the bump bodies 310 may be within a range of about 20 μm to about 40 μm.

Each of the conductive bumps 300 may further include a seed layer 330 that is provided between the bump body 310 and the conductive member 320. The seed layer 330 may strengthen electrical coupling between the bump body 310 and the conductive member 320. The seed layer 330 may provide an electrical movement path between the bump body 310 and the conductive member 320.

For example, the seed layer 330 may include titanium (Ti), titanium nitrogen compound (TiN), titanium oxygen compound (TiO₂), chromium nitrogen compound (CrN), titanium carbon nitrogen compound (TiCN), titanium aluminum nitrogen compound (TiAlN), or an alloy thereof. In example embodiments of the present inventive concept, the semiconductor element 400 may be disposed on the first surface 102 of the package substrate 100. The semiconductor element 400 may be spaced apart from the semiconductor device 200 on the package substrate 100. The semiconductor element 400 may be electrically connected to the semiconductor device 200 to eliminate electrical noise and ensure that power is supplied uniformly. A plurality of the semiconductor elements 400 may be disposed on the package substrate 100. For example, the number of semiconductor elements 400 may range from 2 to 15; however, the present inventive concept is not limited thereto.

For example, the semiconductor element 400 may include a passive element, a multi-layer ceramic capacitor (MLCC), a low inductance chip capacitor (LICC), a die side capacitor (DSC), a land side capacitor (LSC), an inductor, an integrated passive device (IPD), etc.

The semiconductor element 400 may be mounted on the package substrate 100 via the conductive bumps 300. The conductive bumps 300 may be provided on element pads 410. The semiconductor element 400 may be mounted on the package substrate 100 using a flip chip bonding method. The semiconductor element 400 may be electrically connected to the second substrate pads 160. The element pads 410 of the semiconductor element 400 may be electrically connected to the second substrate pads 160 of the package substrate 100 through the conductive bumps 300 that serve as conductive connection members.

The element pads 410 may include first and second pads 412 and 414 provided in both sides of the semiconductor element 400. The element pads 410 may be exposed on the lower surface 402 of the semiconductor element 400. For example, the first and second pads 412 and 414 may extend from an upper surface of the semiconductor element 400 and along side surfaces 404 of the semiconductor element 400 to be disposed on the lower surface 402 of the semiconductor element 400. The first and second pads 412 and 414 may be electrically connected to the conductive members 320.

The lower surface 402 of the semiconductor element 400 may be spaced apart from the first surface 102 of the package substrate 100 by a first distance H1. The first distance H1 may be increased by the bump bodies 310 that are provided within the conductive members 320. For example, the first distance H1 may be within a range of about 40 μm to about 60 μm.

In example embodiments of the present inventive concept, the semiconductor element 400 may include metal oxide barriers 420 provided on a side surface 404 of the semiconductor element 400. The metal oxide barriers 420 may cover at least portions of the side surfaces 404 of the semiconductor element 400. The metal oxide barriers 420 may be provided on the conductive members 320. The metal oxide barriers 420 may be provided on the element pads 410, respectively. The metal oxide barriers 420 may cover at least portions of the element pads 410.

The metal oxide barriers 420 may have an oxide layer. The oxidation layer may include an oxide material that does not mix with the conductive members 320. The metal oxide barriers 420 may prevent solder wetting through the oxide layer. The solder wetting may be a phenomenon in which molten conductive members 320 flow in along the side surface 404 of the semiconductor element 400 during the reflow process.

The metal oxide barriers 420 may block inflow of the conductive members 320 melted during the reflow process. Since surface oxidation easily occurs in surfaces of the metal oxide barriers 420, the metal oxide barriers 420 can block the inflow of the molten conductive members 320. Because the metal oxide barriers 420 block the inflow of the molten conductive members 320, the conductive members 320 may be intensively provided on the lower surface 402 of the semiconductor element 400. Since the conductive members 320 are intensively provided on the lower surface 402 of the semiconductor element 400, the first distance H1 from the first surface 102 of the package substrate 100 to the lower surface 402 of the semiconductor element 400 may be increased.

The metal oxide barriers 420 may include a third metal material whose surface oxidation easily occurs. The third metal material of the metal oxide barriers 420 may be different from the second metal material of the conductive members 320. For example, the metal oxide barriers 420 may include zinc (Zn), nickel (Ni), etc.

In example embodiments of the present inventive concept, the sealing member 500 may be provided to cover the semiconductor device 200 and the semiconductor element 400 and may be disposed on the package substrate 100. The sealing member 500 may fill spaces between the package substrate 100 and the semiconductor element 400. For example, the sealing member may include an epoxy mold compound (EMC).

As mentioned above, the semiconductor element 400 may be electrically connected to the second substrate pads 160 of the package substrate 100 through the conductive bumps 300 during the reflow process. Since the second melting point of the conductive members 320 is lower than the first melting point of the bump bodies 310, during the reflow process, the bump bodies 310 might not be melted and the conductive members 320 may be melted to electrically connect the semiconductor element 400 to the second substrate pads 160. Because the bump bodies 310 are not melted, the bump bodies 310 may support the semiconductor element 400 on the second substrate pads 160.

Additionally, the metal oxide barriers 420 may be provided on the side surface 404 of the semiconductor element 400. The metal oxide barriers 420 may include a material whose surface oxidation easily occurs. Since the metal oxide barriers 420 are easily oxidized, the metal oxide barriers 420 may prevent the conductive members 320 from flowing into the side surface 404 of the semiconductor element 400 during the reflow process. Since the conductive members 320 do not flow into the side surface 404 of the semiconductor element 400, the conductive members 320 may support the semiconductor element 400 such that the lower surface 402 of the semiconductor element 400 is spaced apart from the package substrate 100 by a sufficient distance.

The conductive bumps 300 may increase the space between the semiconductor element 400 and the package substrate 100. The conductive bumps 300 may prevent voids and peeling between the semiconductor element 400 and the package substrate 100 and may prevent foreign substances from remaining between the semiconductor element 400 and the package substrate 100.

Hereinafter, a method of manufacturing the semiconductor package of FIG. 1 will be described.

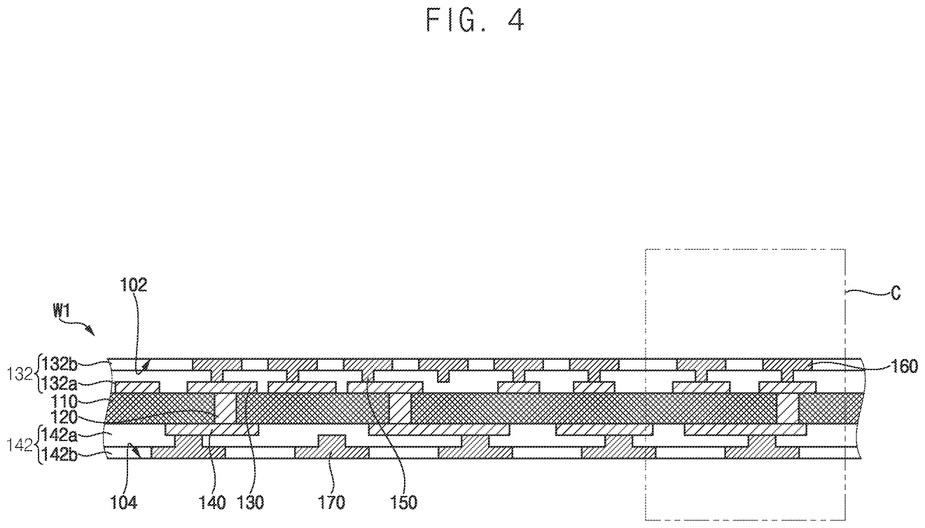

FIGS. 4 to 10 are views illustrating a method of manufacturing a semiconductor package in accordance with example embodiments of the present inventive concept.

Referring to FIG. 4, a package substrate 100 having a first surface 102 and a second surface 104 opposite to each other may be provided.

In example embodiments of the present inventive concept, the package substrate 100 including a core layer 110, a plurality of conductive through vias 120 penetrating the core layer 110, a plurality of upper and lower conductive patterns 130 and 140, upper and lower insulating layers 132 and 142, and a plurality of first to third substrate pads 150, 160 and 170 may be formed.

The core layer 110 may include a non-conductive material layer. The core layer 110 may include a reinforced polymer or the like. The core layer 110 may serve as a boundary layer that divides upper and lower portions of the package substrate 100. The upper insulating layer 132 that includes first and second upper insulating layer 132a and 132b may be formed on the core layer 110. The lower insulating layer 142 that includes first and second lower insulating layers 142a and 142b may be formed on the core layer 110.

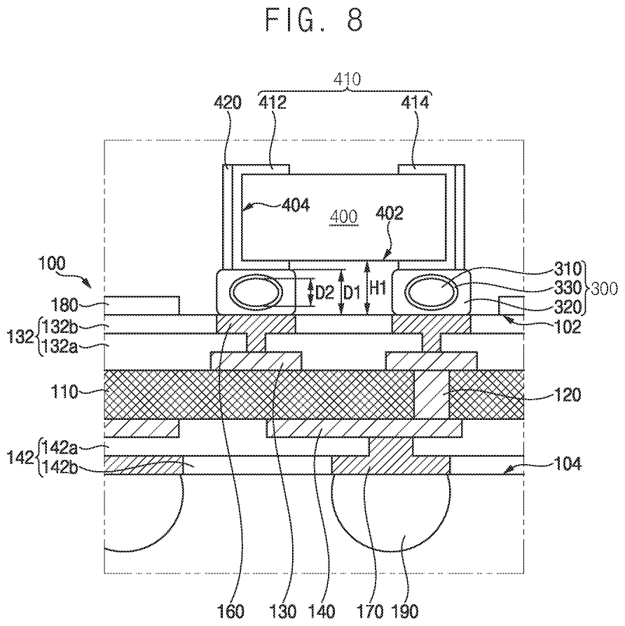

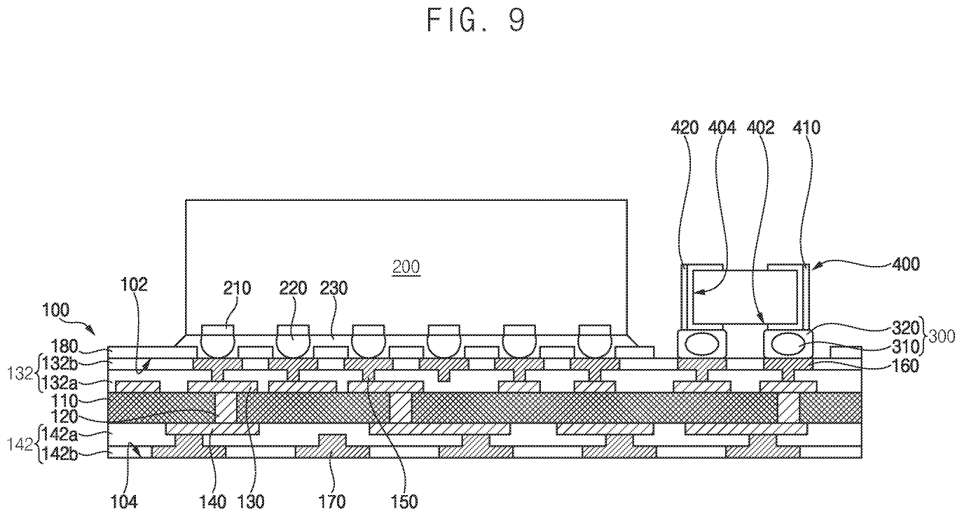

The conductive through via 120 may penetrate the core layer 110 and may electrically connect the upper conductive pattern 130 and the lower conductive pattern 140 to each other. When a semiconductor device 200 (see FIG. 9) and a semiconductor element 400 (see FIG. 8) are mounted on the first surface 102 of the package substrate 100, the conductive through via 120 may be electrically connected to the semiconductor device 200, the semiconductor element 400 and other semiconductor devices that are provided on the second surface 104 of the package substrate 100.

The first upper insulating layer 132a may be formed to cover an upper surface of the core layer 110, and the first lower insulating layer 142a may be formed to cover a lower surface of the core layer 110. The first upper insulating layer 132a may be patterned to form upper opening patterns that expose portions of the upper surface of the core layer 110, and the first lower insulating layer 142a may be patterned to form lower opening patterns that expose portions of the lower surface of the core layer 110.

The upper conductive patterns 130 may be formed on the core layer 110, and the first upper insulating layer 132a may be formed on the upper conductive patterns 130 and may expose portions of the upper conductive patterns 130 through the upper opening patterns of the first upper insulating layer 132a. A first plating process may be performed on the first upper insulating layer 132a to form the upper conductive patterns 130. The lower conductive patterns 140 may be formed on the core layer 110, and the first lower insulating layer 142a may be formed on the lower conductive patterns 140 and may expose portions of the lower conductive patterns 140 through the lower opening patterns of the first lower insulating layer 142a. A second plating process may be performed on the first lower insulating layer 142a to form the lower conductive patterns 140.

For example, the first and second plating processes may include an electrolytic plating process or an electroless plating process. The upper and lower conductive patterns 130 and 140 may include, for example, aluminum (Al), copper (Cu), tin (Sn), nickel (Ni), gold (Au), platinum (Pt), or an alloy thereof.

Then, the second upper insulating layer 132b may be formed on the first upper insulating layer 132a to cover the upper conductive patterns 130, and then, the second upper insulating layer 132b may be patterned to form first and second openings that expose the upper conductive patterns 130. The first substrate pads 150 may be formed on the second upper insulating layer 132b to contact the upper conductive patterns 130 through the first openings. The second substrate pads 160 may be formed on the second upper insulating layer 132b to contact the upper conductive patterns 130 through the second openings.

The second lower insulating layer 142b may be formed on the first lower insulating layer 142a to cover the lower conductive patterns 140, and then, the second lower insulating layer 142b may be patterned to form third openings that expose the lower conductive patterns 140. The third substrate pads 170 may be formed on the second lower insulating layer 142b to contact the lower conductive patterns 140 through the third openings.

For example, the first to third substrate pads 150, 160 and 170 may include aluminum (Al), copper (Cu), tin (Sn), nickel (Ni), gold (Au), platinum (Pt) or an alloy thereof. For example, the upper and lower insulating layers 132 and 142 may include polymer, dielectric layer, etc. For example, the upper and lower insulating layers 132 and 142 may include polyimide (PI), lead oxide (PbO), polyhydroxystyrene (PHS), novolac (NOVOLAC), etc. The upper and lower insulating layers 132 and 142 may be formed by a vapor deposition process, spin coating process, etc.

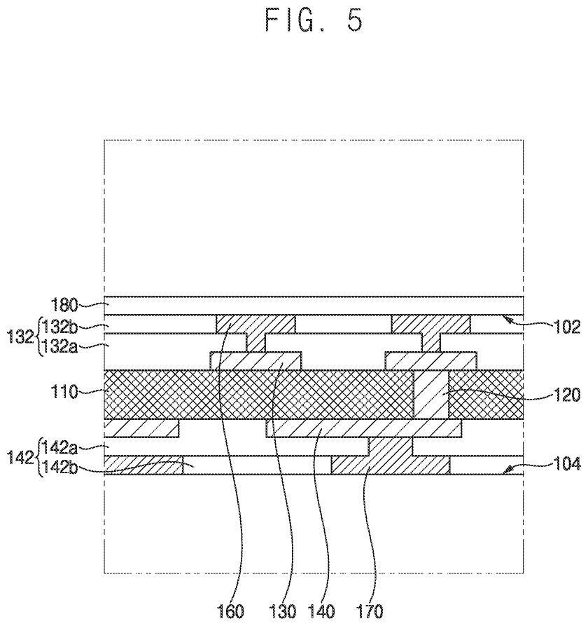

FIGS. 5 to 8 are enlarged cross-sectional views illustrating portion ‘C’ in FIG. 4.

Referring to FIGS. 5 to 7, an uppermost insulating layer 180 may be formed on the upper insulating layer 132 of the package substrate 100, and conductive bumps 300 may be formed on the second substrate pads 160, respectively.

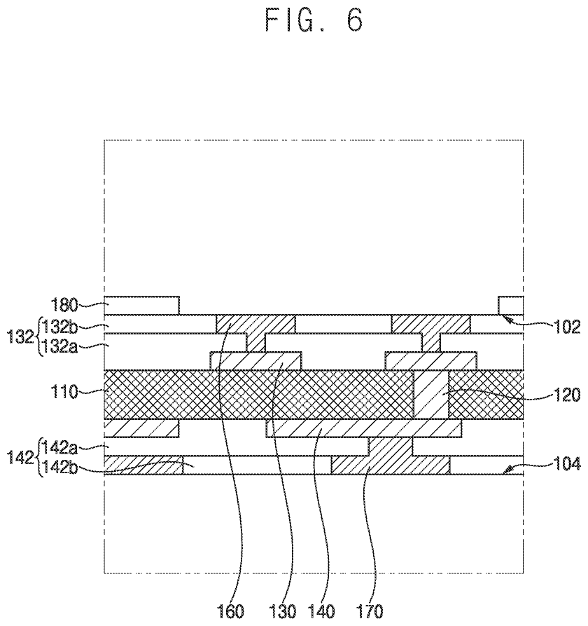

As illustrated in FIGS. 5 and 6, first, the uppermost insulating layer 180 may be formed on the first surface 102 of the package substrate 100, and an etching process may be performed on the first insulating layer 180 to expose the first and second substrate pads 150 and 160. The first and second substrate pads 150 and 160 may be exposed from the first surface 102 of the package substrate 100.

For example, the uppermost insulating layer 180 may be formed by a vapor deposition process, a spin coating process, etc. The uppermost insulating layer 180 may include, for example, a polymer, a dielectric layer, a silicon oxide layer, a silicon nitride layer, or a silicon oxynitride layer.

The etching process may include a wet etching process, a dry etching process, a plasma etching process, etc.

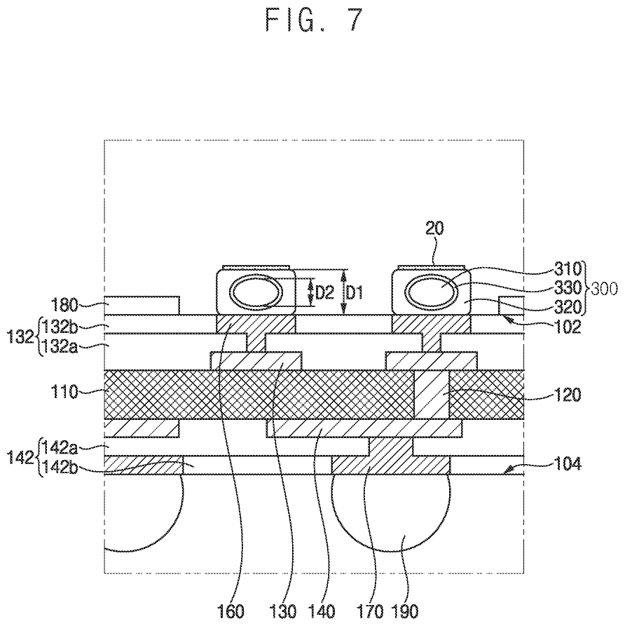

As illustrated in FIG. 7, a plurality of conductive bumps 300 may be disposed on the second substrate pads 160 of the package substrate 100, and fluxes 20 may be formed on the conductive bumps 300, respectively.

Each of the conductive bumps 300 may include a bump body 310 and a conductive member 320 at least partially surrounding the bump body 310. Each of the conductive bumps 300 may further include a seed layer 330 provided between the bump body 310 and the conductive member 320. For example, the conductive bumps 300 may include a Cu Core Solder Ball (CCSB).

At least a portion of the conductive bump 300 may be covered by the flux 20. The flux 20 may produce effects such as oxidation prevention and cleaning of the conductive members 320. The flux 20 may easily bring the conductive bumps 300 into contact with the semiconductor element 400.

Referring to FIG. 8, the semiconductor element 400 may be disposed the plurality of conductive bumps 300.

In example embodiments of the present inventive concept, the semiconductor element 400 may be mounted on the first surface 102 of the package substrate 100 via the plurality of conductive bumps 300. The semiconductor element 400 may be mounted on the package substrate 100 by using a flip chip bonding method.

The semiconductor element 400 may be attached to the first surface 102 of the package substrate 100 by performing a thermal compression process at a predetermined temperature (for example, about 400° C. or less). The thermal compression process may include a reflow process. The reflow process may be a process that applies a high-temperature heat source to stably bond the semiconductor element 400 to the package substrate 100.

In the thermal compression process, an external force may be applied to an upper surface of the semiconductor element 400 and the second surface 104 of the package substrate 100. The semiconductor element 400 and the package substrate 100 may be bonded to each other by the external force and the high temperature heat source. For example, conductive members (solder members) 320 of the semiconductor element 400 may be bonded to the second substrate pads 160 that are formed on the first surface 102 of the package substrate 100, respectively.

In the thermal compression process, the conductive members 320 may be bonded to the second substrate pads 160. The bump bodies 310 may include a first metal material. The conductive members 320 may include a second metal material that is different from the first metal material.

The bump bodies 310 may have a first melting point. The conductive members 320 may have a second melting point that is lower than the first melting point. Since the first melting point of the bump bodies 310 is higher than the second melting point of the conductive members 320, the conductive members 320 may be melted and the bump bodies 310 might not be melted during the reflow process. Since the bump bodies 310 might not be melted when the conductive members 320 are melted, the bump bodies 310 may secure sufficient space between the semiconductor element 400 and the package substrate 100.

The semiconductor element 400 may include metal oxide barriers 420 provided on a side surface 404 thereof. The metal oxide barriers 420 may be provided on element pads 410. The metal oxide barriers 420 may be provided on portion of the conductive members 320.

The metal oxide barriers 420 may block inflow of the conductive members 320 that are melted during the reflow process. Since surface oxidation easily occurs in surfaces of the metal oxide barriers 420, the metal oxide barriers 420 may block the inflow of the molten conductive members 320. Because the metal oxide barriers 420 block the inflow of the molten conductive members 320, the conductive members 320 may be intensively provided on a lower surface 402 of the semiconductor element 400. Since the conductive members 320 are intensively provided on the lower surface 402 of the semiconductor element 400, a first distance H1 from the first surface 102 of the package substrate 100 to the lower surface 402 of the semiconductor element 400 may be increased.

The semiconductor element 400 may be electrically connected to the second substrate pads 160. The element pads 410 of the semiconductor element 400 may be electrically connected to the second substrate pads 160 of the package substrate 100 by the conductive bumps 300 that serve as conductive connection members. For example, the conductive bumps 300 may include micro bumps (uBumps).

Referring to FIG. 9, the semiconductor device 200 may be mounted on the package substrate 100 using the flip chip bonding method. The semiconductor device 200 may be attached to the package substrate 100 by a thermal compression process.

The semiconductor device 200 may be bonded to the first substrate pads 150 by conductive chip bumps 220 that are provided on chip pads 210 thereof. The semiconductor device 200 and the semiconductor element 400 may be electrically connected to each other through the first and second substrate pads 150 and 160 of the package substrate 100 and the conductive bumps 300.

Then, a first adhesive 230 may be underfilled between the semiconductor device 200 and the package substrate 100. The first adhesive 230 may reinforce a gap that is between the semiconductor device 200 and the package substrate 100.

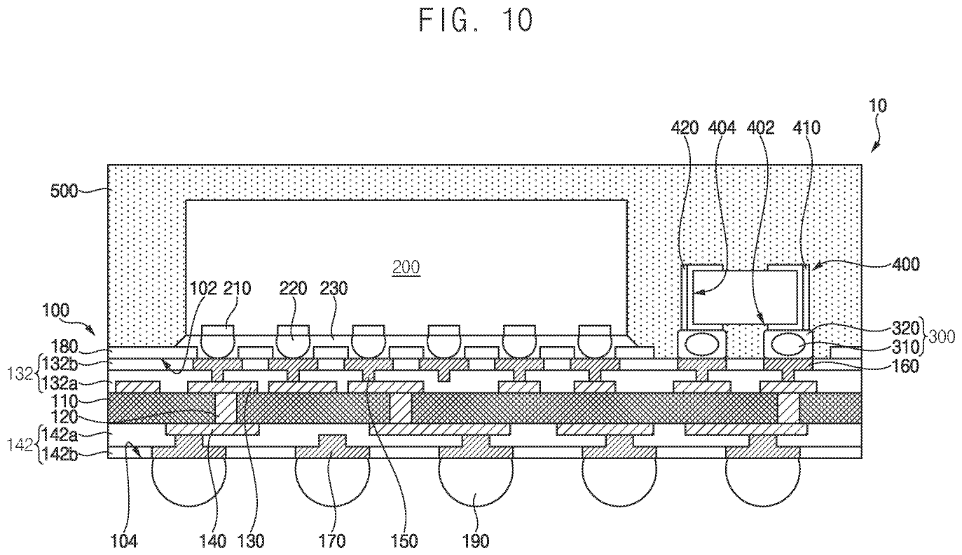

Referring to FIG. 10, external connection bumps 190 such as solder balls may be formed on the third substrate pads 170 that are disposed on the second surface 104 of the package substrate 100, and a sealing member 500 may be formed on the package substrate 100 to cover the semiconductor device 200 and the semiconductor element 400, to form a semiconductor package 10 of FIG. 1.

The external connection bump 190 may be formed on the third substrate pad 170. For example, after a photoresist pattern having temporary openings is formed on the second surface 104 of the package substrate 100, the temporary openings of the photoresist pattern may be filled with a conductive material, the photoresist pattern may be removed and a reflow process may be performed to form the external connection bumps 190. For example, the conductive material may be formed by a plating process. In addition, the external connection bump 190 may be formed by a screen printing method, a vapor deposition method, etc. For example, the external connection bump 190 may include a C4 bump.

The sealing member 500 may be formed on the package substrate 100 to cover the semiconductor device 200 and the semiconductor element 400. The sealing member 500 may fill a space between the package substrate 100 and the semiconductor element 400. Since a sufficient spacing distance is secured between the semiconductor element 400 and the package substrate 100 by the conductive bumps 300, the sealing member 500 may sufficiently fill the space between the semiconductor element 400 and the package substrate 100, and voids may be released to the outside. For example, the sealing member may include an epoxy mold compound (EMC).

In addition, a second adhesive may be underfilled between the semiconductor element 400 and the package substrate 100. The second adhesive may reinforce the gap between the semiconductor element 400 and the package substrate 100. Since a sufficient spacing distance is secured between the semiconductor element 400 and the package substrate 100 by the conductive bumps 300, the second adhesive may sufficiently fill the gap between the semiconductor element 400 and the package substrate 100, and voids may be released to the outside.

The semiconductor package may include semiconductor devices such as logic devices or memory devices. The semiconductor package may include logic devices such as central processing units (CPUs), main processing units (MPUs), application processors (APs), or the like, and volatile memory devices such as DRAM devices, HBM devices, or non-volatile memory devices such as flash memory devices, PRAM devices, MRAM devices, ReRAM devices, or the like.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package, comprising:
a package substrate having a first surface and a second surface opposite to each other, wherein the package substrate includes a plurality of first substrate pads and a plurality of second substrate pads that are exposed from the first surface and are electrically connected to each other;
a semiconductor device mounted on the first surface of the package substrate and electrically connected to the plurality of first substrate pads;
conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and
a semiconductor element mounted on the package substrate via the conductive bumps and spaced apart from the semiconductor device, wherein the semiconductor element has metal oxide barriers that are provided on the conductive members and are provided on a side surface of the semiconductor element.

2. The semiconductor package of claim 1, wherein a lower surface of the semiconductor element is spaced apart from the first surface of the package substrate by a first distance, and
the first distance is within a range of about 40 μm to about 60 μm.

3. The semiconductor package of claim 1, wherein the conductive bumps include a Cu Core Solder Ball (CCSB).

4. The semiconductor package of claim 1, wherein a diameter of each of the bump bodies is within a range of about 20 μm to about 40 μm.

5. The semiconductor package of claim 1, wherein the semiconductor element includes a plurality of elements pads that are disposed on a lower surface of the semiconductor element and are electrically connected to the conductive bumps.

6. The semiconductor package of claim 1, wherein each of the conductive bumps further includes a seed layer that is provided between the bump body and the conductive member.

7. The semiconductor package of claim 1, wherein the bump bodies include at least any one of nickel (Ni), bismuth (Bi), indium (In), aluminum (Al), copper (Cu), lead (Pb), gold (Au), silver (Ag), or polymer.

8. The semiconductor package according to claim 1, wherein the metal oxide barriers include zinc (Zn) or nickel (Ni).

9. The semiconductor package of claim 1, wherein the semiconductor element includes at least one of a passive device, a multi-layer ceramic capacitor (MLCC), a low inductance chip capacitor (LICC), a die side capacitor (DSC), a land side capacitor (LSC), an inductor, and an integrated passive device (IPD).

10. The semiconductor package of claim 1, further comprising:
a sealing member disposed on the package substrate and covering the semiconductor device, the conductive bumps and the semiconductor element.

11. A semiconductor package, comprising:
a package substrate having a first surface and a second surface opposite to each other, wherein the package substrate includes a plurality of first substrate pads and a plurality of second substrate pads that are exposed from the first surface and are electrically connected to each other;
conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and
a semiconductor element mounted on the package substrate via the conductive bumps, wherein the semiconductor element has metal oxide barriers that are provided on the conductive members and that cover at least a portion of a side surface of the semiconductor element.

12. The semiconductor package of claim 11, wherein a lower surface of the semiconductor element is spaced apart from the first surface of the package substrate by a first distance, and
the first distance is within a range of about 40 μm to about 60 μm.

13. The semiconductor package of claim 11, wherein the conductive bumps include a Cu Core Solder Ball (CCSB).

14. The semiconductor package of claim 11, wherein a diameter of each of the bump bodies is within a range of about 20 μm to about 40 μm.

15. The semiconductor package of claim 11, wherein the semiconductor element includes a plurality of elements pads that are disposed on a lower surface of the semiconductor element and are electrically connected to the conductive bumps.

16. The semiconductor package of claim 11, wherein each of the conductive bumps further includes a seed layer that is provided between the bump body and the conductive member.

17. The semiconductor package of claim 11, wherein the bump bodies include at least any one of nickel (Ni), bismuth (Bi), indium (In), aluminum (Al), copper (Cu), lead (Pb), gold (Au), silver (Ag), or polymer.

18. The semiconductor package according to claim 11, wherein the metal oxide barriers include zinc (Zn) or nickel (Ni).

19. The semiconductor package of claim 11, further comprising:
a semiconductor device mounted on the first surface of the package substrate to be spaced apart from the semiconductor element and electrically connected to the plurality of first substrate pads.

20. A semiconductor package, comprising:
a package substrate having a first surface and a second surface opposite to each other, wherein the package substrate includes a plurality of first substrate pads and a plurality of second substrate pads that are exposed from the first surface and are electrically connected to each other;
a semiconductor device mounted on the first surface of the package substrate and electrically connected to the plurality of first substrate pads;
conductive bumps disposed on the plurality of second substrate pads, wherein each of the conductive bumps includes a bump body and a conductive member, wherein the bump body has a first melting point, and the conductive member at least partially surrounds the bump body and has a second melting point that is lower than the first melting point; and
a semiconductor element mounted on the package substrate via the conductive bumps to be electrically connected to the plurality of second substrate pads, wherein the semiconductor element has metal oxide barriers provided on the conductive members and provided on a side surface of the semiconductor element,
wherein the semiconductor element includes a multi-layer ceramic capacitor (MLCC).
